(19) United States
(12) Patent Application Publication
(10) Pub. No.: US 2025/0008816 A1
(43) Pub. Date: Jan. 2, 2025

(54) DISPLAY DEVICE

(71) Applicant: Samsung Display Co., LTD., Yongin-si (KR)

(72) Inventors: Young Seok BAEK, Yongin-si (KR); In Kyung YOO, Yongin-si (KR); Sang Jin PARK, Yongin-si (KR)

(21) Appl. No.: 18/618,004

(22) Filed: Mar. 27, 2024

(30) Foreign Application Priority Data
Jun. 27, 2023 (KR) 10-2023-0082304

(51) Int. Cl. H10K 59/80; H10K 59/122

(52) U.S. Cl. CPC H10K 59/873; H10K 59/122

(57) ABSTRACT

A display device includes: a substrate including a display area and a non-display area surrounding a through-hole; a bank structure positioned on the display area of the substrate, and defining an opening; a light emitting element overlapping the opening; and a pattern structure positioned on the non-display area and between the bank structure and the through-hole. The pattern structure includes a first pattern dam and a second pattern dam spaced apart from each other with a recess portion defined therebetween, the recess portion being recessed toward the substrate, the first pattern dam includes a first pattern layer and a second pattern layer, which include their respective conductive materials different from each other, and a side of the second pattern layer, which is directed toward the recess portion, is more protruded toward the recess portion than a side of the first pattern layer, which is directed toward the recess portion.

This application claims priority to Korean Patent Application No. 10-2023-0082304, filed on Jun. 27, 2023, and all the benefits accruing therefrom under 35 U.S.C. § 119, the content of which in its entirety is herein incorporated by reference.

### BACKGROUND

### 1. Technical Field

The present disclosure relates to a display device.

### 2. Description of the Related Art

With the advancement of the information age, the demand for a display device for displaying an image has increased with various forms. For example, the display device has been applied to various electronic devices such as a smart phone, a digital camera, a laptop computer, a navigator and a smart television. The display device may be a flat panel display device such as a liquid crystal display device, a field emission display device and an organic light emitting display device. Among the flat panel display devices, the light emitting display device includes a light emitting element in which each of pixels of a display panel may self-emit light, thereby displaying an image even without a backlight unit that provides the display panel with light.

### SUMMARY

An aspect of the present disclosure is to provide a display device that resolves a film gap defect near a through-hole.

The aspects of the present disclosure are not limited to those mentioned above and additional aspects of the present disclosure, which are not mentioned herein, will be clearly understood by those skilled in the art from the following description of the present disclosure.

In an embodiment of the disclosure, a display device includes: a substrate including a display area and a non-display area surrounding a through-hole; a bank structure positioned on the display area of the substrate, and defining an opening therein; a light emitting element overlapping the opening in a plan view; and a pattern structure positioned on the non-display area of the substrate and positioned between the bank structure and the through-hole, where the pattern structure includes a first pattern dam and a second pattern dam spaced apart from the first pattern dam with a recess portion defined therebetween, the recess portion being recessed toward the substrate, the first pattern dam includes a first pattern layer and a second pattern layer, which include their respective conductive materials different from each other, and a side of the second pattern layer, which is directed toward the recess portion, is more protruded toward the recess portion than at least a portion of a side of the first pattern layer, which is directed toward the recess portion.

In an embodiment, the bank structure may include a first bank layer and a second bank layer, which include their respective conductive materials different from each other, and a side of the second bank layer may include a tip more protruded toward the opening than a side of the first bank layer.

In an embodiment, the first pattern layer may include the same material as the first bank layer, and the second pattern layer may include the same material as the second bank layer.

In an embodiment, a thickness of the first pattern layer in a direction perpendicular to a major surface of the substrate may be greater than a thickness of the second pattern layer

In an embodiment, the first pattern layer and the first bank layer may include aluminum (Al), and the second pattern layer and the second bank layer may include titanium (Ti).

In an embodiment, a display device may further include a first encapsulation layer positioned on the bank structure and the pattern structure, and including an inorganic material; and a second encapsulation layer positioned on the first encapsulation layer, and including an organic material, where the first encapsulation layer covers the entirety of the pattern structure.

In an embodiment, the second encapsulation layer may be partially in contact with the bank structure, and the second encapsulation layer does not overlap the pattern structure in the plan view.

In an embodiment, a display device may further include a third encapsulation layer overlapped with the non-display area and positioned on the first encapsulation layer, where the third encapsulation layer covers the entirety of the portion of the first encapsulation layer inside the recess portion.

In an embodiment, a display device may further include a main dam positioned between the pattern structure and the bank structure, where the main dam includes a first dam layer and a second dam layer, which include their respective conductive materials different from each other.

In an embodiment, the first dam layer may include the same material as the first bank layer, and the second dam layer includes the same material as the second bank layer.

In an embodiment, the light emitting element may include: a first electrode overlapped with the opening in the plan view; a light emitting layer positioned on the first electrode; and a second electrode positioned on the light emitting layer, and the second electrode may in contact with the side of the first bank layer.

In an embodiment, the second electrode may overlap the protruded tip of the second bank layer in the plan view.

In an embodiment, a display device may further include an organic pattern positioned on the second bank layer, and including the same material as the light emitting layer; and an electrode pattern positioned on the organic pattern, and including the same material as the second electrode.

In an embodiment, the organic pattern may be spaced apart from the light emitting layer, and the electrode pattern is spaced apart from the second electrode.

In an embodiment, the substrate may include an inclined surface in a direction directed toward the through-hole.

In an embodiment, a display device may further include an optical device inside the through-hole.

In an embodiment, the second pattern dam may further include a third pattern layer and a fourth pattern layer, which include their respective conductive materials different from each other, and a side of the fourth pattern layer, which is directed toward the recess portion, is more protruded toward the recess portion than at least a portion of a side of the third pattern layer, which is directed toward the recess portion.

In an embodiment of the disclosure, a display device includes: a substrate including a display area and a non-display area surrounding a through-hole; a bank structure positioned on the display area of the substrate, and defining an opening therein; a light emitting element overlapped with the opening in a plan view; and a pattern structure positioned on the non-display area of the substrate and positioned between the bank structure and the through-hole, where the pattern structure includes a first pattern dam completely surrounding the through-hole in a plan view, the first pattern dam includes a first pattern layer and a second pattern layer, a width of a lower surface of the second pattern layer in a direction parallel with a major surface of the substrate is greater than a width of an upper surface of the first pattern layer in the direction, and opposite sides of the second pattern layer are more protruded than at least portions of opposite sides of the first pattern layer, respectively.

In an embodiment, a display device may further include a second pattern dam completely surrounding the through-hole and the first pattern dam in the plan view, where the second pattern dam may be spaced apart from the first pattern dam with a recess portion defined therebetween, the recess portion being recessed toward the substrate.

In an embodiment, a display device may further include a main dam completely surrounding the first pattern dam and the second pattern dam in the plan view, where the main dam may include a first dam layer and a second dam layer, a first side of the second dam layer facing the bank structure may be more protruded toward the bank structure than at least a portion of a first side of the first dam layer facing the bank structure, and a second side of the second dam layer facing the pattern structure may be more protruded toward the pattern structure than at least a portion of a second side of the first dam layer facing the pattern structure.

The display device according to one embodiment includes a pattern dam near a through-hole, so that a film gap defect near the through-hole may be effectively resolved.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to one embodiment;

FIG. 2 is a plan view illustrating a display panel according to one embodiment;

FIG. 3 is a cross-sectional view illustrating an example of a display device, which is taken along line I-I′ of FIG. 1;

FIG. 4 is a cross-sectional view illustrating an example of a display device in which a circuit board in FIG. 3 is bent;

FIG. 5 is a plan view illustrating arrangement of a light emission area in a display area of a display device according to one embodiment;

FIG. 6 is a cross-sectional view illustrating an example of a display device, which is taken along line XI-XI′ of FIG. 5;

FIG. 7 is an enlarged cross-sectional view illustrating a first light emission area of FIG. 6;

FIG. 8 is an enlarged plan view illustrating an area ‘H’ of FIG. 2;

FIG. 9 is a cross-sectional view illustrating an example of a display panel, which is taken along line HI-HI′ of FIG. 8;

FIG. 10 is a cross-sectional view illustrating a display panel, in which an area ‘J’ of FIG. 9 is enlarged;

FIG. 11 is a cross-sectional view illustrating a display panel, in which an area ‘K’ of FIG. 10 is enlarged;

FIG. 12 is an enlarged plan view illustrating an area ‘Q’ of FIG. 2; and

FIG. 13 is a cross-sectional view illustrating a display device, which is taken along line Y-Y′ of FIG. 12.

### DETAILED DESCRIPTION

Hereinafter, illustrative embodiments will be described with reference to the accompanying drawings.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

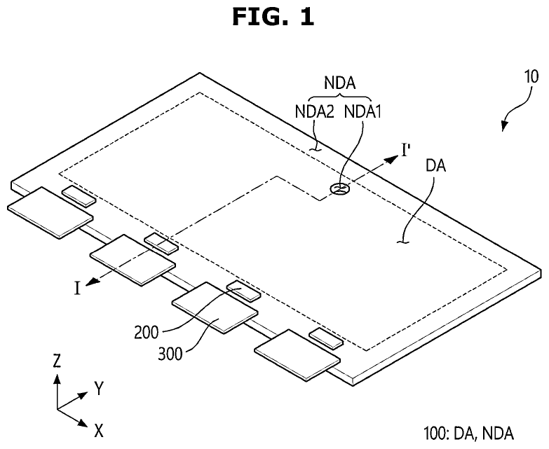

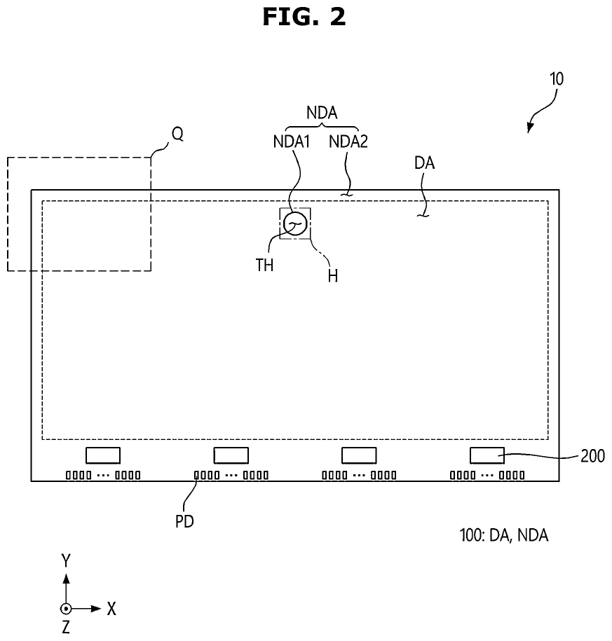

FIG. 1 is a perspective view illustrating a display device according to one embodiment. FIG. 2 is a plan view illustrating a display panel according to one embodiment. As used herein, the “plan view” is a view in a thickness direction (Z-axis direction) of the substrate 110.

Referring to FIG. 1, a display device 10 according to one embodiment is a device that displays a moving image or a still image, and may be used as a display screen of various products such as a television, a laptop computer, a monitor, an advertising board and a device for Internet of things (“IoT”) as well as portable electronic devices such as a mobile phone, a smart phone, a tablet personal computer (“PC”), a smart watch, a watch phone, a mobile communication terminal, an electronic diary, an electronic book, a portable multimedia player (“PMP”), a navigator and an ultra mobile PC (“UMPC”).

The display device 10 according to one embodiment may be a light emitting display device such as an organic light emitting display device using an organic light emitting diode, a quantum dot light emitting display device including a quantum dot light emitting layer, an inorganic light emitting display device including an inorganic semiconductor and a micro (or nano) light emitting display device using a micro (or nano) light emitting diode (micro LED or nano LED). The following description will be based on that the display device 10 is an organic light emitting display device, but the present disclosure is not limited thereto.

The display device 10 according to one embodiment may include a display panel 100, a display driver 200 and a circuit board 300.

The display panel 100 may be formed in a rectangular shaped plane having long sides in a first direction (X-axis direction) and short sides in a second direction (Y-axis direction) crossing the first direction (X-axis direction). A corner where the long side in the first direction (X-axis direction) and the short side in the second direction (Y-axis direction) meet may be formed at a right angle or rounded to have a curvature. The plane shape of the display panel 100 is not limited to the rectangular shape, and may be formed in another polygonal shape, a circular shape or an oval shape.

The display panel 100 may be formed to be flat, but is not limited thereto. For another example, the display panel 100 may include a curved portion formed at left and right ends, having a constant curvature or a variable curvature. In addition, the display panel 100 may be flexibly formed to be curved, bent, folded or rolled.

The display panel 100 may include a display area DA for displaying an image, and a non-display area NDA for not displaying an image.

The display area DA may occupy most of areas of the display panel 100. The display area DA may be disposed at the center of the display panel 100. Pixels, each of which include a plurality of light emission areas, may be disposed in the display area DA to display an image.

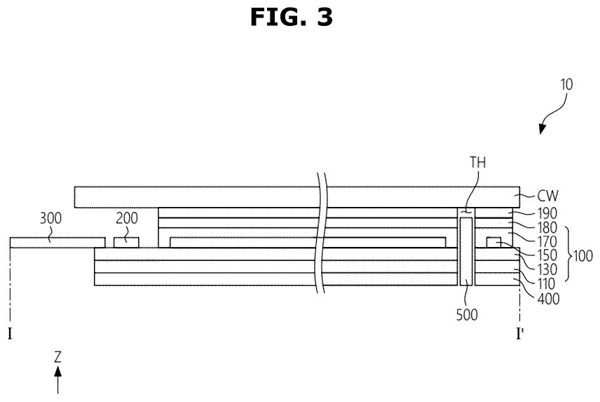

The non-display area NDA may include a first non-display area NDA1 and a second non-display area NDA2. The first non-display area NDA1 may be disposed at one side of the display area DA. The first non-display area NDA1 may be disposed to surround a through-hole TH. The through-hole TH is a hole through which light may be transmitted, and may be an area in which an optical device (‘500’ of FIG. 3) is disposed.

The second non-display area NDA2 may be disposed to be adjacent to the display area DA. The second non-display area NDA2 may be an outer area of the display area DA. The second non-display area NDA2 may be disposed to surround the display area DA. The second non-display area NDA2 may be an edge area of the display panel 100.

Referring to FIGS. 1 and 2, the second non-display area NDA2 may include a display pad PD, a display driver 200 and a circuit board 300.

The display pads PD may be disposed at one edge of the display panel 100. For example, the display pads PD may be disposed at a lower edge of the display panel 100. The display pad PD may be connected to the display driver 200 and the circuit board 300.

The display drivers 200 may generate and output signals and voltages for driving the display panel 100. In detail, the display drivers 200 may generate and output data voltages, power voltages, scan timing signals, and the like. The display drivers 200 may supply the power voltage to a power line, and may supply a gate control signal to a gate driver.

The display drivers 200 may be disposed between the display pads PD and the display area DA in the second non-display area NDA2. The display drivers 200 may be attached to the second non-display area NDA2 of the display panel 100 in a chip on glass (“COG”) manner. Alternatively, the circuit board 300 may be attached to the circuit board 300 in a chip on plastic (“COP”) manner.

The circuit boards 300 may be disposed at one edge of the display panel 100, and may be disposed on the display pads PD. The circuit boards 300 may be attached to the display pads PD by using a conductive adhesive member such as an anisotropic conductive film and an anisotropic conductive adhesive. Therefore, the circuit boards 300 may be electrically connected to signal lines of the display panel 100. The circuit boards 300 may be flexible printed circuit boards or flexible films such as chip on films.

Although not shown, a bending area BA may be disposed between the display driver 200 of the second non-display area NDA2 and the display area DA. The bending area BA may be an area bent so that the display driver 200 and the circuit boards 300 are disposed below the display panel 100. The display driver 200 and the circuit boards 300, which are bent by the bending area BA, may overlap the display area DA in a third direction (Z-axis direction).

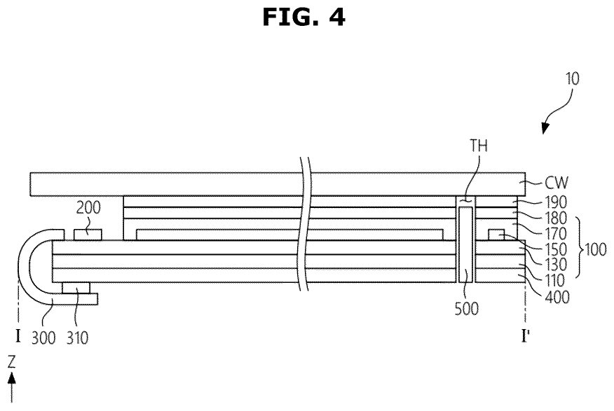

FIG. 3 is a cross-sectional view illustrating an example of a display device, which is taken along line I-I′ of FIG. 1. FIG. 4 is a cross-sectional view illustrating an example of a display device in which a circuit board in FIG. 3 is bent.

Referring to FIG. 3, the display device 10 according to one embodiment may include a display panel 100, a polarizing film 190, a cover window CW and a panel lower cover 400. The display panel 100 may include a substrate 110, a thin film transistor layer 130, a display element layer 150, a thin film encapsulation layer 170 and a touch sensor layer 180.

The substrate 110 may be a base substrate or a base member. The substrate 110 may be a flexible substrate capable of being subjected to bending, folding, rolling and the like. For example, the substrate 110 may include a polymer resin such as polyimide (“PI”), but is not limited thereto. In another embodiment, the substrate 110 may include a glass material or a metal material.

The thin film transistor layer 130 may be disposed on the substrate 110. The thin film transistor layer 130 may include a plurality of thin film transistors. Each of the thin film transistors may include a semiconductor area, a source electrode, a drain electrode and a gate electrode.

The display element layer 150 may be disposed on the thin film transistor layer 130. The display element layer 150 may include a plurality of light emitting elements, which include a pixel electrode, a common electrode and a light emitting layer to emit light, and a pixel defining layer for defining pixels. The plurality of light emitting elements may be disposed in the display area DA.

The thin film encapsulation layer 170 may be positioned on the display element layer 150. The thin film encapsulation layer 170 may cover an upper surface and sides of the display element layer 150 to prevent oxygen or moisture from being permeated into the display element layer 150. The thin film encapsulation layer 170 may include at least one inorganic layer and at least one organic layer.

The touch sensor layer 180 may be disposed on the thin film encapsulation layer 170. The touch sensor layer 180 may include sensor electrodes. The touch sensor layer 180 may sense a user's touch by using the sensor electrodes.

The polarizing film 190 may be disposed on the touch sensor layer 180. The polarizing film 190 may be disposed on the display panel 100 to reduce external light reflection. The polarizing film 190 may include a first base member, a linear polarizing plate, a phase delay film such as a quarter-wave (24) plate and a second base member. The first base member, the phase delay film, the linear polarizing plate and the second base member may be sequentially stacked on the display panel 100.

The cover window CW may be disposed on the polarizing film 190. The cover window CW may be attached onto the polarizing film 190 by a transparent adhesive member such as an optical clear adhesive (“OCA”).

The panel lower cover 400 may be disposed on a lower surface of the substrate 110. The lower surface of the substrate 110 may be an opposite surface of an upper surface. In other words, the lower surface of the substrate 110 may be an opposite surface of a surface on which the thin film transistor layer 130, the display element layer 150, the thin film encapsulation layer 170 and the touch sensor layer 180 are positioned. The panel lower cover 400 may be attached to the lower surface of the substrate 110 through an adhesive member. The adhesive member may be a pressure sensitive adhesive (“PSA”).

The panel lower cover 400 may include at least one of a light blocking member for absorbing light incident from the outside, a buffer member for absorbing an impact from the outside or a heat dissipation member for efficiently discharging heat.

In some embodiments, the display device 10 may further include an optical device 500. The optical device 500 may emit or receive light of an infrared, ultraviolet, or visible band. For example, the optical device 500 may be a proximity sensor, an illuminance sensor, or an optical sensor for sensing light incident on the display device 10, such as a camera sensor or an image sensor.

The optical device 500 may be disposed in the through-hole TH. The through-hole TH is a hole capable of transmitting light, and may be a physical hole passing through the panel lower cover 400, the display panel 100 and the polarizing film 190, but the present disclosure is not limited thereto. The through-hole TH may pass through the panel lower cover 400, but may not pass through the display panel 100 and the polarizing film 190 in another embodiment. The cover window CW may be disposed to cover the through-hole TH.

Referring to FIG. 4, the display driver 200 and the circuit board 300 may be bent toward a lower portion of the display panel 100. The circuit board 300 may be attached to a lower surface of the panel lower cover 400 by an adhesive member 310. The adhesive member 310 may be a pressure sensitive adhesive.

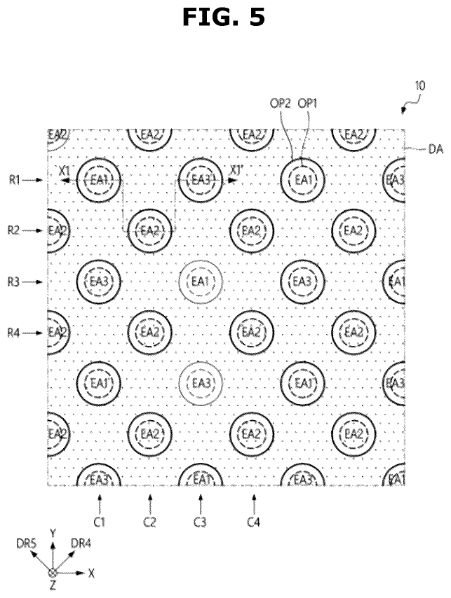

FIG. 5 is a plan view illustrating arrangement of a light emission area EA in a display area DA of a display device 10 according to one embodiment.

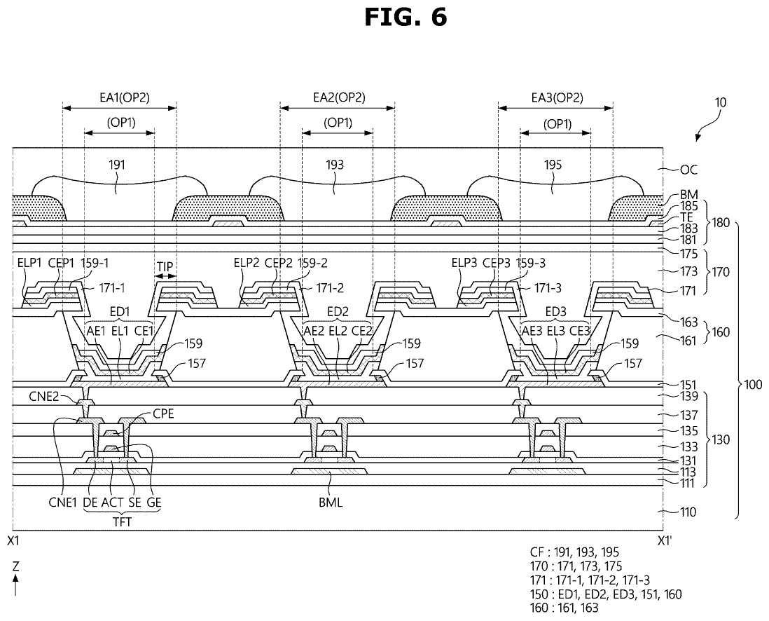

Referring to FIG. 5, the display device 10 may include a plurality of light emission areas EA1, EA2 and EA3 disposed in the display area DA. The light emission areas EA1, EA2 and EA3 may include a first light emission area EA1, a second light emission area EA2 and a third light emission area EA3, which emit light of different colors. The first to third light emission areas EA1, EA2 and EA3 may emit red light, green light and blue light, respectively, and the color of light emitted from each of the light emission areas EA1, EA2 and EA3 may be different depending on types of light emitting elements (‘ED’, ‘ED2’ and ‘ED3’ of FIG. 6) that will be described later. For example, the first light emission area EA1 may emit first light of a red color, the second light emission area EA2 may emit second light of a green color, and the third light emission area EA3 may emit third light of a blue color, but the present disclosure is not limited thereto.

The plurality of light emission areas EA1, EA2 and EA3 may be disposed in a Pentile™ type, for example, a diamond Pentile™ type. For example, the first light emission area EA1 and the third light emission area EA3 may be spaced apart from each other in the first direction DR1, and may be alternately disposed in the first direction DR1 and the second direction DR2. In the arrangement of the light emission areas EA1, EA2 and EA3, the first light emission area EA1 and the third light emission area EA3 may be alternately disposed in the first direction DR1 in a first row R1 and a third row R3. The first light emission area EA1 and the third light emission area EA3 may be alternately disposed in the second direction DR2 in a first column C1 and a third column C3.

The second light emission area EA2 may be spaced apart from another second light emission area EA2 adjacent thereto in the first direction DR1 and the second direction DR2, and may be spaced apart from the first light emission area EA1 and the third light emission area EA3, which are adjacent thereto, in a fourth direction DR4 or a fifth direction DR5. The plurality of second light emission areas EA2 be repeatedly disposed along the first direction DR1 and the second direction DR2, and the second light emission area EA2 and the first light emission area EA1, or the second light emission area EA2 and the third light emission area EA3 may be alternately disposed along the fourth direction DR4 or the fifth direction DR5. In the arrangement of the light emission areas EA1, EA2 and EA3, the second light emission area EA2 may be repeatedly disposed in the first direction DR1 in a second row R2 and a fourth row R4, and the second light emission area EA2 may be repeatedly disposed in the second direction DR2 in a second column C2 and a fourth column C4.

The first to third light emission areas EA1, EA2 and EA3 may be defined by a first opening OP1 defined by a pixel defining layer (151 of FIG. 6) and a second opening OP2 defined by a bank structure (‘160’ of FIG. 6), which will be described later.

In the display device 10, one first light emission area EA1, two second light emission areas EA2 and one third light emission area EA3, which are disposed to be adjacent to one another, may form one pixel group. One pixel group may include light emission areas EA1, EA2 and EA3 that emit light of different colors, thereby representing a white gray scale, but the present disclosure is not limited thereto. Combination of the light emission areas EA1, EA2 and EA3 constituting one pixel group may be modified in various ways depending on the arrangement of the light emission areas EA1, EA2 and EA3 and the colors of light emitted from the light emission areas EA1, EA2 and EA3.

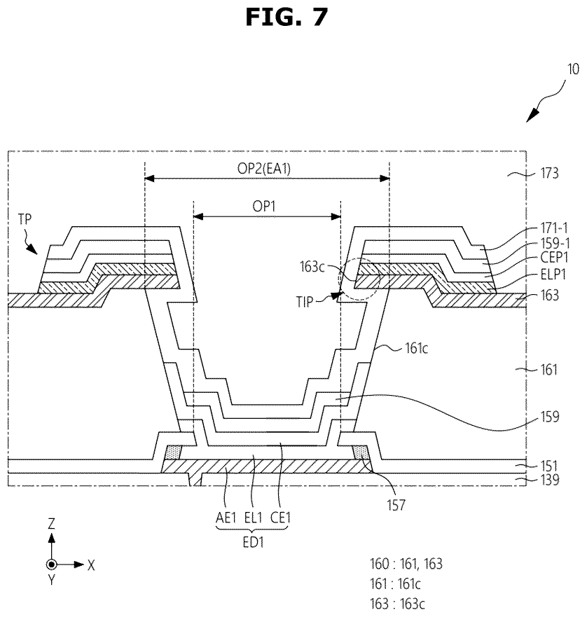

FIG. 6 is a cross-sectional view illustrating an example of a display device 10, which is taken along line XI-XI′ of FIG. 5. FIG. 7 is an enlarged cross-sectional view illustrating a first light emission area of FIG. 6.

Referring to FIG. 6, the display panel 100 may include a substrate 110, a thin film transistor layer 130, a display element layer 150, a thin film encapsulation layer 170 and a touch sensor layer 180.

The substrate 110 has been already mentioned and thus its description will be omitted.

The thin film transistor layer 130 may include a first buffer layer 111, a lower metal layer BML, a second buffer layer 113, a thin film transistor TFT, a gate insulating layer 131, a first interlayer-insulating layer 133, a capacitor electrode CPE, a second interlayer-insulating layer 135, a first connection electrode CNE1, a first passivation layer 137, a second connection electrode CNE2 and a second passivation layer 139.

The first buffer layer 111 may be disposed on the substrate 110. The first buffer layer 111 may include an inorganic layer capable of preventing permeation of the air or moisture. For example, the first buffer layer 111 may include a plurality of inorganic layers that are alternately stacked.

The lower metal layer BML may be disposed on the first buffer layer 111. For example, the lower metal layer BML may be formed of a single layer or multiple layers made of one of molybdenum (Mo), aluminum (Al), chromium (Cr), gold (Au), titanium (Ti), nickel (Ni), neodymium (Nd) and copper (Cu) or their alloy.

The second buffer layer 113 may cover the first buffer layer 111 and the lower metal layer BML. The second buffer layer 113 may include an inorganic layer capable of preventing permeation of the air or moisture. For example, the second buffer layer 113 may include a plurality of inorganic layers that are alternately stacked.

The thin film transistor TFT may be disposed on the second buffer layer 113, and may constitute a pixel circuit of each of the plurality of pixels. For example, the thin film transistor TFT may be a driving transistor or a switching transistor of the pixel circuit. The thin film transistor TFT may include a semiconductor layer ACT, a source electrode SE, a drain electrode DE and a gate electrode GE.

The semiconductor layer ACT may be disposed on the second buffer layer 113. The semiconductor layer ACT may overlap the lower metal layer BML and the gate electrode GE in a thickness direction (i.e., Z-axis direction), and may be insulated from the gate electrode GE by the gate insulating layer 131. A portion of the semiconductor layer ACT may be conductorized to form the source electrode SE and the drain electrode DE.

The gate electrode GE may be disposed on the gate insulating layer 131. The gate electrode GE may overlap the semiconductor layer ACT with the gate insulating layer 131 interposed therebetween in a plan view.

The gate insulating layer 131 may be disposed on the semiconductor layer ACT. For example, the gate insulating layer 131 may cover the semiconductor layer ACT and the second buffer layer 113, and may insulate the semiconductor layer ACT from the gate electrode GE. The gate insulating layer 131 may include a contact hole through which the first connection electrode CNE1 passes.

The first interlayer-insulating layer 133 may cover the gate electrode GE and the gate insulating layer 131. The first interlayer-insulating layer 133 may include a contact hole through which the first connection electrode CNE1 passes. The contact hole of the first interlayer-insulating layer 133 may be connected to a contact hole of the gate insulating layer 131 and a contact hole of the second interlayer-insulating layer 135.

The capacitor electrode CPE may be disposed on the first interlayer-insulating layer 133. The capacitor electrode CPE may overlap the gate electrode GE in the thickness direction (i.e., Z-axis direction). The capacitor electrode CPE and the gate electrode GE may form capacitance.

The second interlayer-insulating layer 135 may cover the capacitor electrode CPE and the first interlayer-insulating layer 133. The second interlayer-insulating layer 135 may include a contact hole through which the first connection electrode CNE1 passes. The contact hole of the second interlayer-insulating layer 135 may be connected to the contact hole of the first interlayer-insulating layer 133 and the contact hole of the gate insulating layer 131.

The first connection electrode CNE1 may be disposed on the second interlayer-insulating layer 135. The first connection electrode CNE1 may electrically connect the drain electrode DE of the thin film transistor TFT with the second connection electrode CNE2. The first connection electrode CNE1 may be inserted into the contact hole formed in the second interlayer-insulating layer 135, the first interlayer-insulating layer 133 and the gate insulating layer 131 to contact the drain electrode DE of the thin film transistor TFT.

The first passivation layer 137 may cover the first connection electrode CNE1 and the second interlayer-insulating layer 135. The first passivation layer 137 may protect the thin film transistor TFT. The first passivation layer 137 may include a contact hole through which the second connection electrode CNE2 passes.

The second connection electrode CNE2 may be disposed on the first passivation layer 137. The second connection electrode CNE2 may electrically connect the first connection electrode CNE1 with pixel electrodes AE1, AE2 and AE3 of the light emitting elements ED1, ED2 and ED3. The second connection electrode CNE2 may be inserted into a contact hole formed in the first passivation layer 137 to contact the first connection electrode CNE1.

The second passivation layer 139 may cover the second connection electrode CNE2 and the first passivation layer 137. The second passivation layer 139 may include a contact hole through which the pixel electrodes AE1, AE2 and AE3 of the light emitting elements ED1, ED2 and ED3 pass.

The display element layer 150 may be disposed on the thin film transistor layer 130. The display element layer 150 may include light emitting elements ED1, ED2 and ED3, an inorganic pixel defining layer 151 and a bank structure 160.

Referring to FIGS. 6 and 7, the light emitting elements ED1, ED2 and ED3 may be disposed on the second passivation layer 139. The light emitting elements ED1, ED2 and ED3 may include pixel electrodes AE1, AE2 and AE3, light emitting layers EL1, EL2 and EL3, and common electrodes CE1, CE2 and CE3.

The pixel electrodes AE1, AE2 and AE3 may be disposed in the plurality of light emission areas EA1, EA2 and EA3, respectively. The pixel electrodes AE1, AE2 and AE3 may include a first pixel electrode AE1 disposed in the first light emission area EA1, a second pixel electrode AE2 disposed in the second light emission area EA2, and a third pixel electrode AE3 disposed in the third light emission area EA3. The pixel electrodes AE1, AE2 and AE3 may be disposed to be spaced apart from one another on the second passivation layer 139. The pixel electrodes AE1, AE2 and AE3 may be disposed in light emission areas EA1, EA2 and EA3 to emit light of different colors, respectively.

The pixel electrodes AE1, AE2 and AE3 may be electrically connected to the drain electrode DE of the thin film transistor TFT through first and second connection electrodes CNE1 and CNE2. In an embodiment, the pixel electrodes AE1, AE2 and AE3 may have a stacked layer structure in which a material layer, which has a high work function, such as indium-tin-oxide (“ITO”), indium-zinc-oxide (“IZO”), zinc oxide (ZnO) and indium oxide (In₂O₃), and a reflective material layer such as Ag, Mg, Al, Pt, Pb, Pd, Au, Ni, Nd, Ir, Cr, Li, Ca or their mixture are stacked. The layer having a high work function may be disposed above the reflective material layer, and thus may be disposed to be close to the light emitting layers EL1, EL2 and EL3. For example, the pixel electrodes AE1, AE2 and AE3 may have a multi-layered structure of ITO/Mg, ITO/MgF, ITO/Ag and ITO/Ag/ITO, but is not limited thereto.

The inorganic pixel defining layer 151 may be positioned on the pixel electrodes AE1, AE2 and AE3. The inorganic pixel defining layer 151 may define a plurality of first openings OP1 for forming the light emission areas EA1, EA2 and EA3. The light emitting elements ED1, ED2 and ED3 may be disposed to overlap the first opening OP1 in a plan view. The inorganic pixel defining layer 151 may be entirely disposed on the second passivation layer 139, and may expose a portion of upper surfaces of the pixel electrodes AE1, AE2 and AE3 while partially overlapping the pixel electrodes AE1, AE2 and AE3 in a plan view.

The inorganic pixel defining layer 151 may include an inorganic insulating material. For example, the inorganic pixel defining layer 151 may include aluminum oxide, titanium oxide, tantalum oxide, hafnium oxide, zinc oxide, silicon oxide, silicon nitride and silicon oxynitride.

The bank structure 160 may be positioned on the inorganic pixel defining layer 151. The bank structure 160 may define a plurality of second openings OP2 for forming the light emission areas EA1, EA2 and EA3. The light emitting elements ED1, ED2 and ED3 may be disposed to overlap the second opening OP2 in a plan view. The bank structure 160 may include a first bank layer 161 and a second bank layer 163, which include their respective metal materials and structures different from each other to serve as different functions.

The first bank layer 161 may be positioned on the inorganic pixel defining layer 151. The first bank layer 161 may include metal having high electrical conductivity. For example, the first bank layer 161 may include aluminum (Al) having high electrical conductivity.

Referring to FIG. 7, the first bank layer 161 may include a side 161c positioned toward the first opening OP1. The side 161c of the first bank layer 161 may be positioned at an oblique angle between the first direction (X-axis direction) and the third direction (Z-axis direction). The bank structure 160 may be formed by deposition and etching processes instead of a mask process, and the first bank layer 161 may be formed by a wet etch process. Therefore, the side 161c of the first bank layer 161 may be more recessed in the first direction (X-axis direction) than the inorganic pixel defining layer 151 and thus may be positioned in an inclined surface shape inclined in the first direction (X-axis direction) based on the third direction (Z-axis direction).

The second bank layer 163 may be positioned on the first bank layer 161. The second bank layer 163 may include a material having an etch rate lower than an etch rate of the first bank layer 161, and for example, the second bank layer 163 may include titanium (Ti).

In some embodiments, the second bank layer 163 may include a side 163c directed toward the first opening OP1. The second bank layer 163 may be formed through a wet etch process like the first bank layer 161. Since the second bank layer 163 includes a material that is relatively stable for a wet etching process as compared with the first bank layer 161, the side 163c of the second bank layer 163 may have a shape more protruded toward the first opening OP1 than at least a portion of the side 161c of the first bank layer 161. The side 161c of the first bank layer 161 may have a shape inwardly recessed from the side 163c of the second bank layer 163. Therefore, the second bank layer 163 of the bank structure 160 may include a tip TIP protruded toward the first opening OP1, and an undercut may be formed between a lower portion of the tip TIP of the second bank layer 163 and the side 161c of the first bank layer 161.

The light emitting layers EL1, EL2 and EL3 may be disposed on the pixel electrodes AE1, AE2 and AE3. The light emitting layers EL1, EL2 and EL3 may be organic light emitting layers made of an organic material, and may be formed on the pixel electrodes AE1, AE2 and AE3 through a deposition process. When the thin film transistor TFT applies a predetermined voltage to the pixel electrodes AE1, AE2 and AE3 and the common electrodes CE1, CE2 and CE3 receive a common voltage or a cathode voltage, holes and electrons may move to the light emitting layers EL1, EL2 and EL3 through a hole transport layer and an electron transport layer, and may be combined with each other in the light emitting layers EL1, EL2 and EL3 to emit light.

The light emitting layers EL1, EL2 and EL3 may include a first light emitting layer EL1, a second light emitting layer EL2 and a third light emitting layer EL3, which are disposed in their respective light emission areas EA1, EA2 and EA3 different from one another. The first light emitting layer EL1 may be disposed on the first pixel electrode AE1 in the first light emission area EA1, the second light emitting layer EL2 may be disposed on the second pixel electrode AE2 in the second light emission area EA2, and the third light emitting layer EL3 may be disposed on the third pixel electrode AE3 in the third light emission area EA3. For example, the first light emitting layer EL1 may be a light emitting layer for emitting red light of a first color, the second light emitting layer EL2 may be a light emitting layer for emitting green light of a second color, and the third light emitting layer EL3 may be a light emitting layer for emitting blue light of a third color.

In some embodiments, the inorganic pixel defining layer 151 may be disposed on the pixel electrodes AE1, AE2 and AE3, and may be spaced apart from the upper surfaces of the pixel electrodes AE1, AE2 and AE3. In a fabricating process of the display device 10, a temporary protective layer may be disposed between the inorganic pixel defining layer 151 and the pixel electrodes AE1, AE2 and AE3 and then may be partially removed. Thus, a lower surface of the inorganic pixel defining layer 151 may be spaced apart from the pixel electrodes AE1, AE2 and AE3 in an area from which the temporary protective layer is partially removed. The light emitting layers EL1, EL2 and EL3 may be disposed in a portion of an area spaced between the inorganic pixel defining layer 151 and the pixel electrodes AE1, AE2 and AE3. A deposition process of the light emitting layers EL1, EL2 and EL3 may be performed so that the material of the light emitting layers EL1, EL2 and EL3 are deposited in an inclined direction rather than in a direction (i.e., thickness direction) perpendicular to the upper surface (i.e., major surface) of the substrate 110. Therefore, the light emitting layers EL1, EL2 and EL3 may be disposed to fill a space between the pixel electrodes AE1, AE2 and AE3 and the inorganic pixel defining layer 151. A portion of the temporary protective layer, which is not removed, may remain as a residual pattern 157 in the area spaced between the pixel electrodes AE1, AE2 and AE3 and the inorganic pixel defining layer 151. In other words, the area spaced between the pixel electrodes AE1, AE2 and AE3 and the inorganic pixel defining layer 151 may be filled with the residual pattern 157 and the light emitting layers EL1, EL2 and EL3.

The common electrodes CE1, CE2 and CE3 may be disposed on the light emitting layers EL1, EL2 and EL3. The common electrodes CE1, CE2 and CE3 may include a transparent conductive material to emit light generated from the light emitting layers EL1, EL2 and EL3. The common electrodes CE1, CE2 and CE3 may receive a common voltage or a low potential voltage. When the pixel electrodes AE1, AE2 and AE3 receive a voltage corresponding to the data voltage and the common electrodes CE1, CE2 and CE3 receive the low potential voltage, a potential difference may be formed between the pixel electrodes AE1, AE2 and AE3 and the common electrodes CE1, CE2 and CE3, whereby the light emitting layers EL1, EL2 and EL3 may emit light.

For example, the common electrodes CE1, CE2 and CE3 may include silver (Ag), but are not limited thereto. The common electrodes CE1, CE2, CE3 may include all of material layers having a low work function, such as Li, Ca, LiF/Ca, LiF/Al, Al, Mg, Pt, Pd, Ni, Au Nd, Ir, Cr, BaF, Ba or their compound or mixture (e.g., mixture of Ag and Mg). The common electrodes CE1, CE2 and CE3 may further include a transparent metal oxide layer disposed on the material layer having a low work function.

The common electrodes CE1, CE2 and CE3 may include a first common electrode CE1, a second common electrode CE2 and a third common electrode CE3, which are disposed in their respective light emission areas EA1, EA2 and EA3 different from one another. The first common electrode CE1 may be disposed on the first light emitting layer EL1 in the first light emission area EA1, the second common electrode CE2 may be disposed on the second light emitting layer EL2 in the second light emission area EA2, and the third common electrode CE3 may be disposed on the third light emitting layer EL3 in the third light emission area EA3.

In the display device 10 according to one embodiment of the present disclosure, the common electrodes CE1, CE2 and CE3 disposed in the different light emission areas EA1, EA2 and EA3 may be electrically connected to one another through the first bank layer 161 of the bank structure 160 without being directly connected to one another. Therefore, a portion of the common electrodes CE1, CE2 and CE3 may be disposed on a side of the first bank layer 161 of the bank structure 160.

A capping layer 159 may be disposed on the common electrodes CE1, CE2 and CE3. The capping layer 159 may include an inorganic insulating material to cover the light emitting elements ED1, ED2 and ED3. The capping layer 159 may prevent the light emitting elements ED1, ED2 and ED3 from being damaged from the external air. In an embodiment, the capping layer 159 may include aluminum oxide, titanium oxide, tantalum oxide, hafnium oxide, zinc oxide, silicon oxide, silicon nitride and silicon oxynitride.

Referring to FIG. 6, a plurality of organic patterns ELP1, ELP2 and ELP3, electrode patterns CEP1, CEP2 and CEP3 and capping patterns 159-1, 159-2 and 159-3 may be positioned on the second bank layer 163. The plurality of organic patterns ELP1, ELP2 and ELP3, the electrode pattern CEP1, CEP2 and CEP3 and the capping patterns 159-1, 159-2 and 159-3 may be disposed to surround the periphery of the light emission areas EA1, EA2 and EA3 or the first openings OP1. A stacked structure of the plurality of organic patterns ELP1, ELP2 and ELP3, the electrode patterns CEP1, CEP2 and CEP3 and the capping patterns 159-1, 159-2 and 159-3, which are disposed in the periphery of the light emission areas EA1, EA2 and EA3, may be partially etched in the fabricating process of the display device 10 so that a pattern shape may be changed. Therefore, a portion of an upper surface of the second bank layer 163 of the bank structure 160 may not be covered by the plurality of organic patterns ELP1, ELP2 and ELP3, the electrode patterns CEP1, CEP2 and CEP3 and the capping patterns 159-1, 159-2 and 159-3, and a trench portion TP may be formed in the portion of the upper surface of the second bank layer 163 by the patterns.

The plurality of organic patterns ELP1, ELP2 and ELP3 may be formed on the second bank layer 163 to partially overlap the second bank layer 163 in a plan view. Each of the organic patterns ELP1 and ELP2 and ELP3 may include the same material as each of the light emitting layers EL1, EL2, EL3. The first organic pattern ELP1 may include the same material as the first light emitting layer EL1 of the first light emitting element ED1, the second organic pattern ELP2 may include the same material as the second light emitting layer EL2 of the second light emitting element ED2, and the third organic pattern ELP3 may include the same material as the third light emitting layer EL3 of the third light emitting element ED3. Since the bank structure 160 includes the tip TIP, the organic patterns ELP1, ELP2 and ELP3 may be marks formed as being disconnected without being connected to the light emitting layers EL1, EL2 and EL3.

The plurality of electrode patterns CEP1, CEP2 and CEP3 may be disposed on the plurality of organic patterns ELP, ELP and ELP3, respectively. The electrode patterns CEP1, CEP2 and CEP3 may include the first electrode pattern CEP1, the second electrode pattern CEP2 and the third electrode pattern CEP3, each of which includes the same material as the common electrodes CE1, CE2 and CE3. For example, the first electrode pattern CEP1, the second electrode pattern CEP2 and the third electrode pattern CEP3 may be disposed directly on the first organic pattern ELP1, the second organic pattern ELP2 and the third organic pattern ELP3, respectively. The arrangement relation of the electrode patterns CEP1, CEP2 and CEP3 and the organic patterns ELP1, ELP2 and ELP3 may be the same as the arrangement relation of the light emitting layers EL1, EL2 and EL3 and the common electrodes CE1, CE2 and CE3. Since the bank structure 160 includes the tip TIP, the electrode patterns CEP1, CEP2 and CEP3 may be marks formed as the deposited material is disconnected without being connected to the common electrodes CE1, CE2 and CE3. In the display device 10, the common electrodes CE1, CE2 and CE3 may be individually formed in different areas by the tip TIP of the bank structure 160 even in a deposition process in which a mask is not used.

The plurality of capping patterns 159-1, 159-2 and 159-3 may be positioned on the plurality of electrode patterns CEP1, CEP2 and CEP3. The plurality of capping patterns 159-1, 159-2 and 159-3 may include the same material as the capping layer 159. The arrangement relation between the capping patterns 159-1, 159-2 and 159-3 and the plurality of electrode patterns CEP1, CEP2 and CE3 may be the same as the arrangement relation between the capping layer 159 and the common electrodes CE1, CE2 and CE3. Since the bank structure 160 includes the tip TIP, the capping patterns 159-1, 159-2 and 159-3 may be marks formed as the capping layer 159 is disconnected. The capping patterns 159-1, 159-2 and 159-3 may prevent delamination of a plurality of patterns from occurring during the fabricating process.

The thin film encapsulation layer 170 may be disposed on the light emitting elements ED1, ED2 and ED3, the bank structure 160 and the plurality of patterns, and may cover the plurality of light emitting elements ED1, ED2 and ED3, the bank structure 160 and the plurality of patterns. The thin film encapsulation layer 170 may include at least one inorganic layer to prevent oxygen or moisture from being permeated into the display element layer 150. The thin film encapsulation layer 170 may include at least one organic layer to protect the display element layer 150 from particles such as dust. In an embodiment, the thin film encapsulation layer 170 may include a first encapsulation layer 171, a second encapsulation layer 173 and a third encapsulation layer 175, which are sequentially stacked. The first encapsulation layer 171 and the third encapsulation layer 175 may be inorganic encapsulation layers, and the second encapsulation layer 173 disposed between the first encapsulation layer 171 and the third encapsulation layer 175 may be an organic encapsulation layer.

Each of the first encapsulation layer 171 and the third encapsulation layer 175 may include one or more inorganic insulating materials. The inorganic insulating material may include aluminum oxide, titanium oxide, tantalum oxide, hafnium oxide, zinc oxide, silicon oxide, silicon nitride and silicon oxynitride.

The second encapsulation layer 173 may include a polymer-based material. The polymer-based material may include an acrylic resin, an epoxy-based resin, polyimide and polyethylene. For example, the second encapsulation layer 173 may include an acrylic resin, for example, polymethyl methacrylate, polyacrylic acid or the like. The second encapsulation layer 173 may be formed by curing a monomer or coating a polymer.

The first encapsulation layer 171 may include first to third inorganic layers 171-1, 171-2 and 171-3 disposed to correspond to the different light emission areas EA1, EA2 and EA3, respectively.

The first to third inorganic layers 171-1, 171-2 and 171-3 may be disposed to cover the organic patterns ELP1, ELP2 and ELP3, the electrode patterns CEP1, CEP2 and CEP3 and the capping patterns 159-1, 159-2 and 159-3. Since the first to third inorganic layers 171-1, 171-2 and 171-3 may be formed by chemical vapor deposition (“CVD”), the first to third inorganic layers 171-1, 171-2 and 171-3 may be formed to have a uniform thickness along a step difference of the layers that are deposited. For example, the first to third inorganic layers 171-1, 171-2 and 171-3 may form a thin film even below an undercut caused by the tip TIP of the bank structure 160.

The first inorganic layer 171-1 may be disposed on the first light emitting element ED1 and the first electrode pattern CEP1 to overlap the first light emission area EA1 in a plan view. The first inorganic layer 171-1 may be disposed to cover the first light emitting element ED1, the sidewall of the bank structure 160, the first organic pattern ELP1, the first electrode pattern CEP1 and the capping pattern 159-1. However, the first inorganic layer 171-1 may be disposed only on the first light emission area EA1 and the bank structure 160 near the first light emission area EA1 without overlapping the second light emission area EA2 and the third light emission area EA3 in a plan view.

The second inorganic layer 171-2 may be disposed on the second light emitting element ED2 and the second electrode pattern CEP2 to overlap the second light emission area EA2 in a plan view. The second inorganic layer 171-2 may be disposed to cover the second light emitting element ED2, the sidewall of the bank structure 160, the second organic pattern ELP2, the second electrode pattern CEP2 and the capping pattern 159-2. However, the second inorganic layer 171-2 may be disposed only on the second light emission area EA2 and the bank structure 160 near the second light emission area EA2 without overlapping the first light emission area EA1 and the third light emission area EA3 in a plan view.

The third inorganic layer 171-3 may be disposed on the third light emitting element ED3 and the third electrode pattern CEP3 to overlap the third light emission area EA3 in a plan view. The third inorganic layer 171-3 may be disposed to cover the third light emitting element ED3, the sidewall of the bank structure 160, the third organic pattern ELP3, the third electrode pattern CEP3 and the capping pattern 159-3. However, the third inorganic layer 171-3 may be disposed only on the third light emission area EA3 and the bank structure 160 near the third light emission area EA3 without overlapping the first light emission area EA1 and the second light emission area EA2 in a plan view.

In some embodiments, the first inorganic layer 171-1 may be formed after the first common electrode CE1 is formed, the second inorganic layer 171-2 may be formed after the second common electrode CE2 is formed, and the third inorganic layer 171-3 may be formed after the third common electrode CE3 is formed. Therefore, the first to third inorganic layers 171-1, 171-2 and 171-3 may be disposed to cover the different electrode patterns CEP1, CEP2 and CEP3 and the organic patterns ELP1, ELP2 and ELP3, respectively.

The first to third inorganic layers 171-1, 171-2 and 171-3 may be disposed to be spaced apart from one another on the bank structure 160. Therefore, a portion of the second bank layer 163 of the bank structure 160 may not overlap the first to third inorganic layers 171-1, 171-2 and 171-3 in a plan view. Therefore, a portion of the upper surface of the second bank layer 163 may be exposed without being covered by the first to third inorganic layers 171-1, 171-2 and 171-3. The exposed portion of the upper surface of the second bank layer 163 may be in contact with the second encapsulation layer 173.

The touch sensor layer 180 may be disposed on the thin film encapsulation layer 170. The touch sensor layer 180 may include a touch buffer layer 181, a touch insulating layer 183, a touch electrode TE and a touch passivation layer 185.

The touch buffer layer 181 may be disposed on the thin film encapsulation layer 170. The touch buffer layer 181 may have insulating and optical functions. The touch buffer layer 181 may include at least one inorganic layer. Optionally, the touch buffer layer 181 may be omitted. Although not shown, the connection electrode electrically connecting the touch electrodes may be disposed on the touch buffer layer 181. The connection electrode may be formed of a single layer of molybdenum (Mo), titanium (Ti), copper (Cu), aluminum (Al), or indium tin oxide (ITO), or may be formed of a stacked structure (Ti/Al/Ti) of aluminum and titanium, a stacked structure (ITO/AI/ITO) of aluminum and ITO, an Ag—Pd—Cu (“APC”) alloy, or a stacked structure (ITO/APC/ITO) of an APC alloy and ITO.

The touch insulating layer 183 may cover the touch buffer layer 181. The touch insulating layer 183 may have an insulating function. For example, the touch insulating layer 183 may be an inorganic layer that includes at least one of a silicon nitride layer, a silicon oxynitride layer, a silicon oxide layer, a titanium oxide layer or an aluminum oxide layer.

A portion of the touch electrode TE may be disposed on the touch insulating layer 183. Each of the touch electrodes TE may not overlap the first to third light emission areas EA1, EA2 and EA3 in a plan view. Each of the touch electrodes TE may be formed of a single layer of molybdenum (Mo), titanium (Ti), copper (Cu), aluminum (Al), or indium tin oxide (ITO), or may be formed of a stacked structure (Ti/Al/Ti) of aluminum and titanium, a stacked structure (ITO/Al/ITO) of aluminum and ITO, an APC alloy or a stacked structure (ITO/APC/ITO) of an APC alloy and ITO.

The touch passivation layer 185 may cover the touch electrode TE and the touch insulating layer 183. The touch passivation layer 185 may have insulating and optical functions. The touch passivation layer 185 may be formed of the material exemplified as the touch insulating layer 183.

A light blocking layer BM may be disposed on the touch sensor layer 180. The light blocking layer BM may be disposed to overlap the inorganic pixel defining layer 151 and the bank structure 160 in a plan view. The light blocking layer BM may include a light absorbing material. For example, the light blocking layer BM may include an inorganic black pigment or an organic black pigment. The inorganic black pigment may be carbon black, and the organic black pigment may include at least one of lactam black, perylene black or aniline black, but is not limited thereto. The light blocking layer BM may prevent color mixture from occurring due to permeation of visible light among the first to third light emission areas EA1, EA2 and EA3, thereby improving a color reproduction rate of the display device 10.

The color filter layer CF may be disposed on the touch passivation layer 185 and the light blocking layer BM by overlapping the light emission areas EA1, EA2 and EA3 in a plan view.

The color filter layer CF may include a first color filter 191, a second color filter 193 and a third color filter 195, which are disposed to correspond to the different light emission areas EA1, EA2 and EA3, respectively. The plurality of color filters 191, 193 and 195 may include a colorant such as a dye or a pigment, which absorbs light of a wavelength band other than light of a specific wavelength band, and may be disposed to correspond to a color of light emitted from the light emission areas EA1, EA2 and EA3. For example, the first color filter 191 may be a red color filter disposed to overlap the first light emission area EA1, for transmitting only the first light of the red color. The second color filter 193 may be a green color filter disposed to overlap the second light emission area EA2, for transmitting only the second light of the green color, and the third color filter 195 may be a blue color filter disposed to overlap the third light emission area EA3, for transmitting only the third light of the blue color.

FIG. 6 shows that the plurality of color filters 191, 193 and 195 are spaced apart from other color filters 191, 193 and 195 adjacent thereto on the light blocking layer BM, but the present disclosure is not limited thereto. In other words, the plurality of color filters 191, 193 and 195 may be disposed to partially overlap other color filters 191, 193 and 195 adjacent thereto. That is, the different color filters 191, 193 and 195 do not overlap the light emission areas EA1, EA2 and EA3, and may overlap one another on the light blocking layer BM in a plan view.

An overcoat layer OC may be disposed on the color filter layer CF and the light blocking layer BM to planarize upper ends of the plurality of color filters 191, 193 and 195. The overcoat layer OC may be a colorless light-transmissive layer that does not have a color of a visible light band. For example, the overcoat layer OC may include a colorless light-transmissive organic material such as an acryl-based resin.

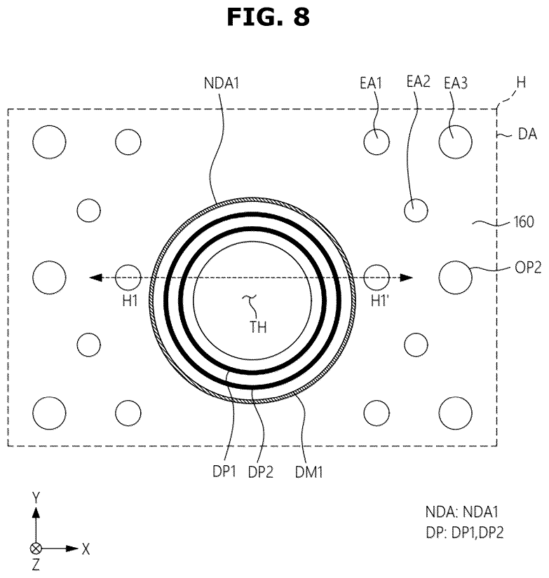

FIG. 8 is an enlarged plan view illustrating an area ‘H’ of FIG. 2.

Referring to FIG. 8, the first non-display area NDA1 may be disposed to surround the periphery of the through-hole TH. A main dam DM1 and a pattern dam DP may be positioned in the first non-display area NDA1.

The main dam DM1 may be a boundary between the display area DA and the first non-display area NDA1. The display device 10 may have a structure in which a plurality of layers are sequentially stacked on one substrate 110. Several layers of the display device 10 are made of an organic material, and may be formed through a process in which the organic material is directly coated onto the substrate 110. For example, the second encapsulation layer 173 of the thin film encapsulation layer 170 may include an organic material and thus may flow while having fluidity. The organic material coated onto the display area DA may overflow to the non-display area NDA. Therefore, the main dam DM1 may be positioned in the first non-display area NDA1, and may prevent organic materials disposed in the display area DA from overflowing into the through-hole TH.

In some embodiments, the main dam DM1 is formed as the bank structure 160 positioned in the display area DA is extended, and then may be formed in the form of the main dam DM1 shown by an etching process during the fabricating process. That is, the bank structure 160 and the main dam DM1 are integrated into one body, and then may be separated from each other by an etching process performed during the fabricating process. Therefore, the main dam DM1 may include the same material and characteristics as those of the bank structure 160.

The pattern dam DP may be positioned between the through-hole TH and the main dam DM1. The pattern dam DP may be referred to as “pattern structure.” The pattern dam DP may prevent a film gap near the through-hole TH. For example, the film gap near the through-hole TH may be caused by compression and tensile stress included in the first encapsulation layer 171 and the third encapsulation layer 175 of the thin film encapsulation layer 170. The display device 10 may increase a contact area between the first and third encapsulation layers 171 and 175 and a lower structure by forming the pattern dam DP. Therefore, a film gap defect near the through-hole of the display device 10 may be resolved.

In some embodiments, the pattern dam DP may be formed as the bank structure 160 positioned in the display area DA and the main dam DM1 are extended, and then may be formed in the form of the pattern dam DP as shown by the etching process during the fabricating process. That is, the pattern dam DP may be integrated with the main dam DM1 positioned in the first non-display area NDA1 and the bank structure 160, and then may be separated from the main dam DM1 and the bank structure 160 by the etching process performed during the fabricating process. Therefore, the pattern dam DP may include the same material and characteristics as those of the bank structure 160.

In some embodiments, the pattern dam DP may include a first pattern dam DP1 and a second pattern dam DP2. The first pattern dam DP1 may be disposed to surround the periphery of the through-hole TH in a plan view. The second pattern dam DP2 may be positioned to surround the first pattern dam DP1 and the through-hole TH.

The display area DA may include a bank structure 160 that defines the second opening OP2. The light emitting elements ED1, ED2 and ED3 may be disposed in each of the second openings OP2 to form the light emission areas EA1, EA2 and EA3.

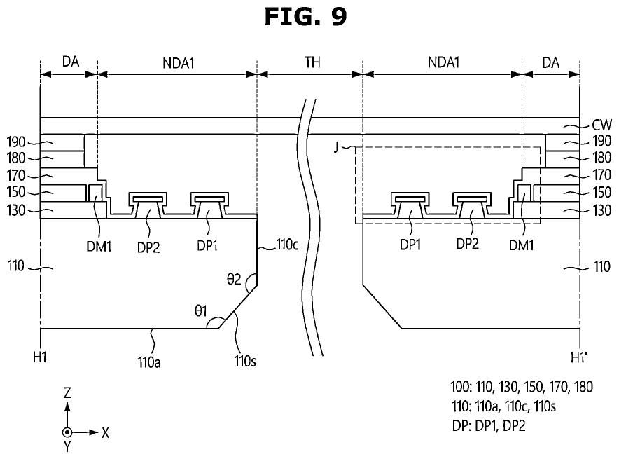

FIG. 9 is a cross-sectional view illustrating an example of a display panel, which is taken along line HI-HI′ of FIG. 8.

Referring to FIG. 9, the through-hole TH may pass through the substrate 110, the thin film transistor layer 130, the display element layer 150, the thin film encapsulation layer 170, the touch sensor layer 180 and the polarizing film 190, which are included in the display panel 100. The through-hole TH may be covered by the cover window CW. The through-hole TH may be formed through a laser processing process. Although not shown in the drawing, the optical device 500 may be disposed inside the through-hole TH.

The substrate 110 may include a first surface 110a, a side 110c and an inclined surface 110s by overlapping the first non-display area NDA1 in a plan view. The inclined surface 110s of the substrate 110 may be a surface connecting the first surface 110a with the side 110c of the substrate 110. The inclined surface 110s of the substrate 110 may be formed by a laser processing process for forming the through-hole TH. In detail, the inclined surface 110s of the substrate 110 may be formed by spraying an etching solution after irradiating laser. An angle θ1 formed by the first surface 110a and the inclined surface 110s of the substrate 110 and an angle θ2 formed by the side 110c and the inclined surface 110s of the substrate 110 may be obtuse angles.

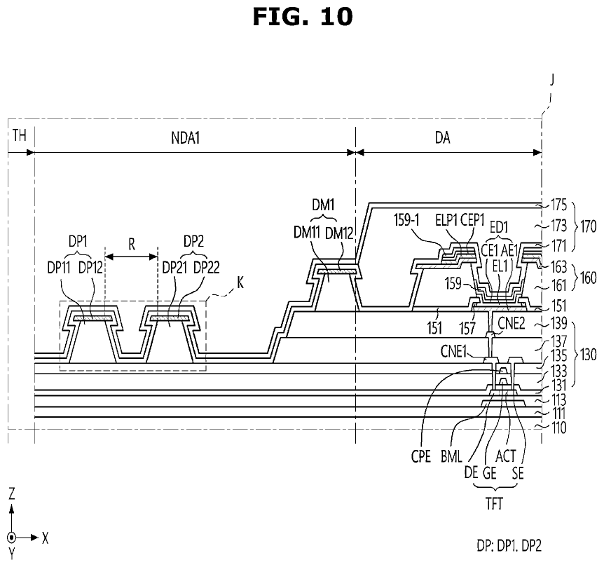

FIG. 10 is a cross-sectional view illustrating a display panel, in which an area ‘J’ of FIG. 9 is enlarged.

Referring to FIG. 10, the main dam DM1 may be disposed on the second passivation layer 139. As described above, the main dam DM1 may prevent the organic material coated onto the display area DA from overflowing to the non-display area NDA. Therefore, the main dam DM1 is desirable to have at least a minimum thickness or height for the above function.

In some embodiments, the main dam DM1 may include a first dam layer DM11 and a second dam layer DM12. The main dam DM1 may have a height capable of preventing the organic material from overflowing by including the first dam layer DM11 and the second dam layer DM12. The first dam layer DM11 included in the main dam DM1 may include the same material and characteristics as those of the first bank layer 161 of the bank structure 160, and the second dam layer DM12 included in the main dam DM1 may include the same material and characteristics as those of the second bank layer 163 of the bank structure 160.

The first dam layer DM11 may include the same material and characteristics as those of the first bank layer 161 of the bank structure 160. For example, the first dam layer DM11 may include aluminum (Al) having high electrical conductivity. The second dam layer DM12 may include the same material and characteristics as those of the second bank layer 163 of the bank structure 160. For example, the second dam layer DM12 may be a material having a low etch rate, and may include titanium (Ti).

For convenience of description, the main dam DM1 is shown as one and the first dam layer DM11 and the second dam layer DM12 are shown as being disposed to be alternate once, but the present disclosure is not limited thereto. That is, the plurality of main dams DM1 may be positioned, and the plurality of first dam layers DM11 and the plurality of second dam layers DM12 may be alternately stacked several times in another embodiment. That is, the main dam DM1 may have a multi-layered structure in which the first dam layer DM11 and the second dam layer DM12 are repeatedly stacked.

As shown in FIG. 10, the first encapsulation layer 171 may be positioned on the main dam DM1, and may cover the entirety of the main dam DM1. The first encapsulation layer 171 may be extended to a boundary of the first non-display area NDA1 beyond the main dam DM1. Therefore, the first encapsulation layer 171 may stop oxygen and moisture, which are permeated by the through-hole TH.

The second encapsulation layer 173 may be positioned on the first encapsulation layer 171 by overlapping the display area DA in a plan view. The second encapsulation layer 173 may be disposed so as not to cover an upper surface of the main dam DM1. The second encapsulation layer 173 may not overflow to the first non-display area NDA1 by the main dam DM1. Therefore, the second encapsulation layer 173 may not overlap the first non-display area NDA1 in a plan view.

The third encapsulation layer 175 may be disposed on the second encapsulation layer 173 by overlapping the display area DA, and may be disposed on the first encapsulation layer 171 by overlapping the first non-display area NDA1 in a plan view. The third encapsulation layer 175 may be extended to the boundary of the first non-display area NDA1 beyond the main dam DM1. Therefore, the first encapsulation layer 171 and the third encapsulation layer 175 may stop oxygen and moisture, which are permeated by the through-hole TH.

In some embodiments, the pattern dam DP may be positioned between the main dam DM1 and the through-hole TH. The pattern dam DP may be positioned on the second buffer layer 113. The pattern dam DP may include a first pattern dam DP1 and a second pattern dam DP2.

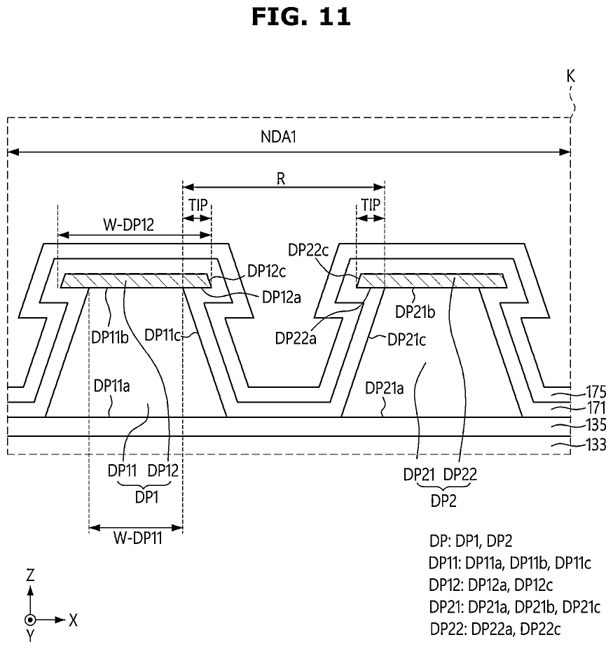

FIG. 11 is a cross-sectional view illustrating a display panel, in which an area ‘K’ of FIG. 10 is enlarged.

Referring to FIG. 11, the first pattern dam DP1 and the second pattern dam DP2 may be positioned to be spaced apart from each other in the first direction (X-axis direction). A recess portion R recessed in a direction directed toward the substrate 110 may be included between the first pattern dam DP1 and the second pattern dam DP2, which are spaced apart from each other.

In some embodiments, the first pattern dam DP1 may include a first pattern layer DP11 and a second pattern layer DP12. The first pattern layer DP11 and the second pattern layer DP12 may include the same structure and characteristics as those of the first bank layer 161 and the second bank layer 163 of the bank structure 160.

The first pattern layer DP11 may be positioned on the second interlayer-insulating layer 135. The first pattern layer DP11 may include metal having high electrical conductivity, and for example, may include aluminum (Al).

In some embodiments, the first pattern layer DP11 may include a lower surface DP11a, an upper surface DP11b, and a side DP11c. The lower surface DP11a of the first pattern layer DP11 may be positioned in contact with the second interlayer-insulating layer 135. The side DP11c of the first pattern layer DP11 may be positioned toward the recess portion R, and may connect the lower surface DP11a with the upper surface DP11b. The side DP11c of the first pattern layer DP11 may be positioned to form an oblique angle between the first direction (X-axis direction) and the third direction (Z-axis direction), but is not limited thereto. The side DP11c of the first pattern layer DP11 may be positioned to be perpendicular to the first direction (X-axis direction). The upper surface DP11b of the first pattern layer DP11 may be in contact with the second pattern layer DP12.

The second pattern layer DP12 may be positioned on the first pattern layer DP11. A thickness of the first pattern layer DP11 in a direction (i.e., Z-axis direction) perpendicular to the major surface of the substrate 110 may be greater than a thickness of the second pattern layer DP12. The second pattern layer DP12 may include the same material and characteristics as the material and characteristics of the second bank layer 163 of the bank structure 160. For example, the second pattern layer DP12 may include a material having a low etch rate, and may include titanium (Ti).

In some embodiments, the second pattern layer DP12 may include a lower surface DP12a and a side DP12c. The lower surface DP12a of the second pattern layer DP12 may be in contact with the first pattern layer DP11. A width W-DP12 of the lower surface DP12a of the second pattern layer DP12 may be greater than a width W-DP11 of the upper surface DP11b of the first pattern layer DP11. The side DP12c of the second pattern layer DP12 may have a shape more protruded toward the recess portion R than at least a portion of the side DP11c of the first pattern layer DP11. Therefore, the second pattern layer DP12 may include a protruded tip TIP. This may be caused as the second pattern layer DP12 includes a material that is relatively stable for a wet etching process as compared with the first pattern layer DP11. Therefore, an undercut may be formed between a lower portion of the tip TIP of the second pattern layer DP12 and the side DP11c of the first pattern layer DP11.

The second pattern dam DP2 may include a first pattern layer DP21 and a second pattern layer DP22. The first pattern layer DP21 and the second pattern layer DP22 may include the same structure and characteristics as those of the first bank layer 161 and the second bank layer 163 of the bank structure 160. In addition, the first pattern layer DP21 of the second pattern dam DP2 may include the same structure and characteristics as those of the first pattern layer DP11 of the first pattern dam DP1, and the second pattern layer DP22 of the second pattern dam DP2 may include the same structure and characteristics as those of the second pattern layer DP12 of the first pattern dam DP1.

In some embodiments, the first pattern layer DP21 of the second pattern dam DP2 may include a lower surface DP21a, an upper surface DP21b and a side DP21c, and the second pattern layer DP22 may include a lower surface DP22a and a side DP22c. A width of the upper surface DP21b of the first pattern layer DP21 may be smaller than a width of the lower surface DP22a of the second pattern layer DP22. In addition, the side DP22c of the second pattern layer DP22 may be formed to be more protruded toward the recess portion R than at least a portion of the side DP21c of the first pattern layer DP21, whereby the second pattern layer DP22 may include the protruded tip TIP.

The first encapsulation layer 171 may cover the entirety of the first pattern dam DP1 and the second pattern dam DP2. The first encapsulation layer 171 may cover a curved portion included in the pattern dam DP inside the recess portion R formed by the pattern dam DP. For example, the first encapsulation layer 171 may cover an undercut lower portion by the second pattern layer DP12 of the first pattern dam DP1 and the second pattern layer DP22 of the second pattern dam DP2. As described above, the display device 10 may include the pattern dam DP so that an area, in which the first encapsulation layer 171 of the display device 10 is in contact with a lower structure, may be increased. Therefore, the display device 10 may resolve the film gap of the first encapsulation layer 171 during the fabricating process.

The third encapsulation layer 175 may be positioned on the first encapsulation layer 171 by overlapping the first pattern dam DP1 and the second pattern dam DP2 in a plan view. In the display area DA, the second encapsulation layer 173 may be positioned between the first encapsulation layer 171 and the third encapsulation layer 175, but the first encapsulation layer 171 and the third encapsulation layer 175 may be in contact with each other by overlapping the first non-display area NDA1 in a plan view. In other words, the third encapsulation layer 175 may cover the first encapsulation layer 171 by overlapping the first non-display area NDA1 in a plan view. For example, the third encapsulation layer 175 may cover the undercut lower portion by the second pattern layer DP12 of the first pattern dam DP1 and the second pattern layer DP22 of the second pattern dam DP2 along the first encapsulation layer 171. In addition, the other description has been already mentioned and thus will be omitted.

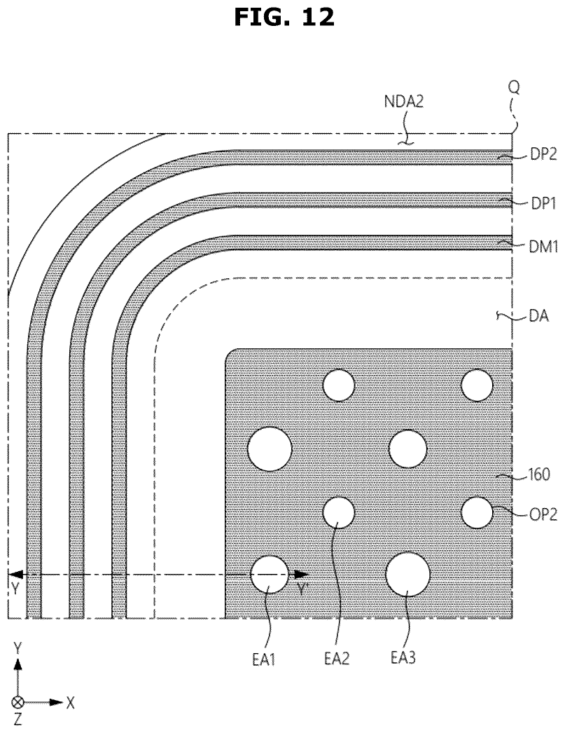

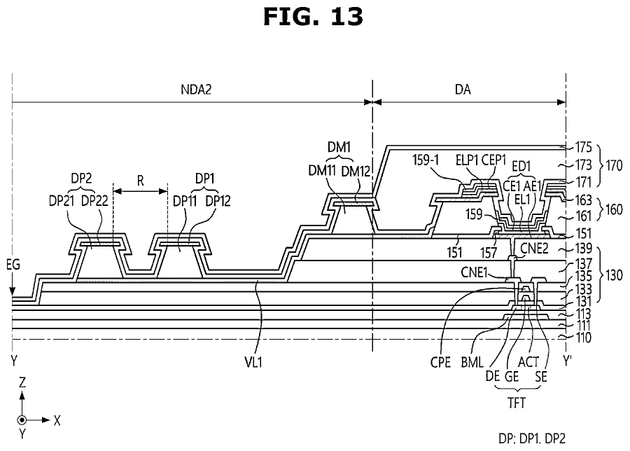

FIG. 12 is an enlarged plan view illustrating an area ‘Q’ of FIG. 2. FIG. 13 is a cross-sectional view illustrating a display device, which is taken along line Y-Y′ of FIG. 12.

Referring to FIGS. 12 and 13, the main dam DM1 surrounding the display area DA may be positioned in the second non-display area NDA2. The main dam DM1 may be positioned on the second passivation layer 139. As described above, the main dam DM1 may be formed to prevent the organic material in the display area DA from overflowing to the non-display area NDA. For example, in the second non-display area NDA2, the second encapsulation layer 173 may not flow to the non-display area NDA by the main dam DM1.

In some embodiments, the main dam DM1 positioned in the second non-display area NDA2 may include a first dam layer DM11 and a second dam layer DM12. A width of the first dam layer DM11 in the first direction (X-axis direction) may be smaller than a width of the second dam layer DM12. In addition, opposite sides of the second dam layer DM12 may be more protruded toward opposite sides of the first direction (X-axis direction) than opposite sides of the first dam layer DM11, respectively. A shape of the first dam layer DM11 and the second dam layer DM12 may be the same as the first bank layer 161 and the second bank layer 163.

Referring to FIG. 12, the pattern dam DP may overlap the second non-display area NDA2 in a plan view, and may be positioned to surround the main dam DM1. The pattern dam DP may include a first pattern dam DP1 and a second pattern dam DP2. The first pattern dam DP1 may overlap the second non-display area NDA2 in a plan view, and may be positioned to surround the main dam DM1. In addition, the second pattern dam DP2 may overlap the second non-display area NDA2 in a plan view, and may be positioned to surround the first pattern dam DP1 and the main dam DM1.

Referring to FIG. 13, the pattern dam DP may overlap the second non-display area NDA2 in a plan view, and may be positioned between the main dam DM1 and an end EG of the substrate 110. The first pattern dam DP1 may be positioned to be close to the main dam DM1, and the second pattern dam DP2 may be positioned to be close to the end EG of the substrate 110. The pattern dam DP may be positioned on a first power line VL1. The main dam DM1 and the pattern dam DP, which are positioned in the second non-display area NDA2, may be electrically connected to the bank structure 160 positioned in the display area DA through the first power line VL1. As mentioned above, the common electrodes CE1, CE2 and CE3 of the display device 10 may be electrically connected to one another through the bank structure 160.

In some embodiments, the pattern dam DP positioned in the second non-display area NDA2 is integrated with the bank structure 160 positioned in the display area DA and the main dam DM1 positioned in the second non-display area NDA2, and then may be separated from the bank structure 160 and the main dam DM1 by an etching process performed during the fabricating process. Therefore, the pattern dam DP may have a shape of the first pattern dam DP1 and the second pattern dam DP2, which are shown in FIG. 13. The first pattern dam DP1 and the second pattern dam DP2 may be positioned to be spaced apart from each other in the first direction (X-axis direction). A recess portion R recessed toward the substrate 110 may be included between the first pattern dam DP1 and the second pattern dam DP2, which are spaced apart from each other.

In some embodiments, the first pattern dam DP1 that overlaps the second non-display area NDA2 in a plan view may include a first pattern layer DP11 and a second pattern layer DP12. The first pattern layer DP11 and the second pattern layer DP12 may include the same structure and characteristics as those of the first bank layer 161 and the second bank layer 163 of the bank structure 160. In detail, the first pattern layer DP11 may include metal having high electrical conductivity, and for example, may include aluminum (Al). The second pattern layer DP12 may be positioned on the first pattern layer DP11. The second pattern layer DP12 may include the same material and characteristics as those of the second bank layer 163 of the bank structure 160. For example, the second pattern layer DP12 may include a material having a low etch rate, and may include titanium (Ti). The second pattern layer DP12 may include a material that is relatively stable for a wet etching process as compared with the first pattern layer DP11, and thus may have a shape more protruded toward the recess portion R than at least a portion of the first pattern layer DP11.

The second pattern dam DP2 that overlaps the second non-display area NDA2 in a plan view may include a first pattern layer DP21 and a second pattern layer DP22. The first pattern layer DP21 and the second pattern layer DP22 may include the same structure and characteristics as those of the first bank layer 161 and the second bank layer 163 of the bank structure 160. In addition, the first pattern layer DP21 of the second pattern dam DP2 may include the same structure and characteristics as those of the first pattern layer DP11 of the first pattern dam DP1, and the second pattern layer DP22 of the second pattern dam DP2 may include the same structure and characteristics as those of the second pattern layer DP12 of the first pattern dam DP1. A side of the second pattern layer DP22 may be formed to be more protruded toward the recess portion R than at least a portion of a side of the first pattern layer DP21.

The first encapsulation layer 171 may cover the entirety of the first pattern dam DP1 and the second pattern dam DP2 by overlapping the second non-display area NDA2 in a plan view. The first encapsulation layer 171 may cover the entirety of the first pattern layer DP11 and the second pattern layer DP12 of the first pattern dam DP1 and the first pattern layer DP21 and the second pattern layer DP22 of the second pattern dam DP2. As an area of the first encapsulation layer 171, which is in contact with the first pattern dam DP1 and the second pattern dam DP2, is increased, a film gap may be resolved.

The third encapsulation layer 175 may be positioned on the first encapsulation layer 171 by overlapping the second non-display area NDA2 in a plan view. The third encapsulation layer 175 may cover the first encapsulation layer 171 on the first pattern dam DP1 and the second pattern dam DP2. The third encapsulation layer 175 may cover the entirety of the first encapsulation layer 171 inside the recess portion R between the first pattern dam DP1 and the second pattern dam DP2. The other description has been already mentioned and thus will be omitted.

However, the effects of the disclosure are not restricted to the one set forth herein. The above and other effects of the disclosure will become more apparent to one of daily skill in the art to which the disclosure pertains by referencing the claims.

What is claimed is:

1. A display device comprising:
a substrate including a display area and a non-display area surrounding a through-hole;
a bank structure positioned on the display area of the substrate, and defining an opening therein;
a light emitting element overlapping the opening in a plan view; and
a pattern structure positioned on the non-display area of the substrate and positioned between the bank structure and the through-hole,
wherein the pattern structure includes a first pattern dam and a second pattern dam spaced apart from the first pattern dam with a recess portion defined therebetween, the recess portion being recessed toward the substrate,
the first pattern dam includes a first pattern layer and a second pattern layer, which include their respective conductive materials different from each other, and
a side of the second pattern layer, which is directed toward the recess portion, is more protruded toward the recess portion than at least a portion of a side of the first pattern layer, which is directed toward the recess portion.

2. The display device of claim 1, wherein the bank structure includes a first bank layer and a second bank layer, which include their respective conductive materials different from each other, and
a side of the second bank layer includes a tip more protruded toward the opening than a side of the first bank layer.

3. The display device of claim 2, wherein the first pattern layer includes a same material as the first bank layer, and
the second pattern layer includes a same material as the second bank layer.

4. The display device of claim 3, wherein a thickness of the first pattern layer in a direction perpendicular to a major surface of the substrate is greater than a thickness of the second pattern layer.

5. The display device of claim 4, wherein the first pattern layer and the first bank layer include aluminum (Al), and
the second pattern layer and the second bank layer include titanium (Ti).

6. The display device of claim 1, further comprising:
a first encapsulation layer positioned on the bank structure and the pattern structure, and including an inorganic material; and
a second encapsulation layer positioned on the first encapsulation layer, and including an organic material,
wherein the first encapsulation layer covers an entirety of the pattern structure.

7. The display device of claim 6, wherein the second encapsulation layer is partially in contact with the bank structure, and
the second encapsulation layer does not overlap the pattern structure in the plan view.

8. The display device of claim 7, further comprising a third encapsulation layer overlapped with the non-display area and positioned on the first encapsulation layer,
wherein the third encapsulation layer covers an entirety of a portion of the first encapsulation layer, which is inside the recess portion.

9. The display device of claim 2, further comprising a main dam positioned between the pattern structure and the bank structure,
wherein the main dam includes a first dam layer and a second dam layer, which include their respective conductive materials different from each other.

10. The display device of claim 9, wherein the first dam layer includes a same material as the first bank layer, and
the second dam layer includes a same material as the second bank layer.

11. The display device of claim 2, wherein the light emitting element includes:
a first electrode overlapped with the opening in the plan view;
a light emitting layer positioned on the first electrode; and
a second electrode positioned on the light emitting layer,
wherein the second electrode is in contact with the side of the first bank layer.

12. The display device of claim 11, wherein the second electrode overlaps the protruded tip of the second bank layer in the plan view.

13. The display device of claim 11, further comprising:
an organic pattern positioned on the second bank layer, and including a same material as the light emitting layer; and
an electrode pattern positioned on the organic pattern, and including a same material as the second electrode.

14. The display device of claim 13, wherein the organic pattern is spaced apart from the light emitting layer, and the electrode pattern is spaced apart from the second electrode.

15. The display device of claim 1, wherein the substrate includes an inclined surface in a direction directed toward the through-hole.

16. The display device of claim 15, further comprising an optical device inside the through-hole.

17. The display device of claim 1, wherein the second pattern dam further includes a third pattern layer and a fourth pattern layer, which include their respective conductive materials different from each other, and
a side of the fourth pattern layer, which is directed toward the recess portion, is more protruded toward the recess portion than at least a portion of a side of the third pattern layer, which is directed toward the recess portion.

18. A display device comprising:
a substrate including a display area and a non-display area surrounding a through-hole;
a bank structure positioned on the display area of the substrate, and defining an opening therein;
a light emitting element overlapped with the opening in a plan view; and
a pattern structure positioned on the non-display area of the substrate and positioned between the bank structure and the through-hole,
wherein the pattern structure includes a first pattern dam completely surrounding the through-hole in a plan view,
the first pattern dam includes a first pattern layer and a second pattern layer,
a width of a lower surface of the second pattern layer in a direction parallel with a major surface of the substrate is greater than a width of an upper surface of the first pattern layer in the direction, and
opposite sides of the second pattern layer are more protruded than at least portions of opposite sides of the first pattern layer, respectively.

19. The display device of claim 18, further comprising a second pattern dam completely surrounding the through-hole and the first pattern dam in the plan view,
wherein the second pattern dam is spaced apart from the first pattern dam with a recess portion defined therebetween, the recess portion being recessed toward the substrate.

20. The display device of claim 19, further comprising a main dam completely surrounding the first pattern dam and the second pattern dam in the plan view,
wherein the main dam includes a first dam layer and a second dam layer,
a first side of the second dam layer facing the bank structure is more protruded toward the bank structure than at least a portion of a first side of the first dam layer facing the bank structure, and
a second side of the second dam layer facing the pattern structure is more protruded toward the pattern structure than at least a portion of a second side of the first dam layer facing the pattern structure.
